(19) United States
(12) Patent Application Publication
(10) Pub. No.: US 2026/0005024 A1
(43) Pub. Date: Jan. 1, 2026

(54) METHOD OF FORMING A SEMICONDUCTOR DEVICE INCLUDING A PLASMA DOPING PROCESS

(71) Applicant: Infineon Technologies AG, Neubiberg (DE)

(72) Inventors: Werner Schustereder, Villach (AT); Fabian Rasinger, Villach (AT); Ravi Keshav Joshi, Klagenfurt am Wörthersee (AT); Hans-Joachim Schulze, Taufkirchen (DE); Thomas Ralf Siemieniec, Villach (AT)

(21) Appl. No.: 19/250,142

(22) Filed: Jun. 26, 2025

(30) Foreign Application Priority Data
Jun. 26, 2024 (DE) 102024118086.2

(51) Int. Cl. H01L 21/04; H01L 21/223; H10D 64/01

(52) U.S. Cl. CPC H01L 21/0465; H01L 21/2236; H10D 64/027

(57) ABSTRACT

A method of forming a semiconductor device is proposed. The method includes forming a doped region of a first conductivity type in a SiC semiconductor body. Forming the doped region includes introducing dopants of the first conductivity type into the SiC semiconductor body by at least one ion implantation process. Forming the doped region further includes introducing dopants of the first conductivity type into the SiC semiconductor body by at least one plasma doping process. A penetration depth of the dopants introduced by the at least one ion implantation process is larger than a penetration depth of the dopants introduced by the at least one plasma doping process. The method further includes forming a contact material on a contact surface portion of the doped region. The contact surface portion includes the dopants introduced by at least plasma doping process.

### TECHNICAL FIELD

The present disclosure relates to a method of forming a semiconductor device, in particular to a method of forming a doped region of a semiconductor device including introducing dopants into a SiC semiconductor body by at least one ion implantation process.

### BACKGROUND

A key component in semiconductor applications is a solid state switch. As an example, switches turn loads of automotive applications or industrial applications on and off. Solid state switches typically include, for example, field effect transistors (FETs) like metal-oxide-semiconductor FETs (MOSFETs) or insulated gate bipolar transistors (IGBTs) or junction field effect transistors (JFETs). Technology development of new generations of SiC semiconductor switches aims at improving electrical device characteristics and reducing costs by shrinking device geometries. Although costs may be reduced by shrinking device geometries, a variety of tradeoffs and challenges have to be met when increasing device functionalities per unit area. For example, reducing the area-specific on-state resistance, Ron x A, by shrinking device geometries may be challenging in view of ohmic contact formation on doped regions in trenches or small mesa regions.

There is a need for improving formation methods of SiC semiconductor devices.

### SUMMARY

An example of the present disclosure relates to a method of forming a semiconductor device. The method includes forming a doped region of a first conductivity type in a SiC semiconductor body. Forming the doped region includes introducing dopants of the first conductivity type into the SiC semiconductor body by at least one ion implantation process. Forming the doped region further includes introducing dopants of the first conductivity type into the SiC semiconductor body by at least one plasma doping process. A penetration depth of the dopants introduced by the at least one ion implantation process is larger than a penetration depth of the dopants introduced by the at least one plasma doping process. The method further includes forming a contact material on a contact surface portion of the doped region, wherein the contact surface portion includes the dopants introduced by at least plasma doping process.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of semiconductor devices and methods of manufacturing semiconductor devices and together with the description serve to explain principles of the embodiments. Further embodiments are described in the following detailed description and the claims.

FIG. 1 is an exemplary process illustration of manufacturing a semiconductor device.

FIGS. 2A and 2B are schematic cross-sectional views for illustrating process features of forming a doped region including a plasma doping process.

FIGS. 3A to 3E are schematic cross-sectional views related to FIG. 2A for illustrating process features of manufacturing a semiconductor device.

FIGS. 4A and 4B are schematic cross-sectional views related to FIG. 2B for illustrating process features of manufacturing a semiconductor device.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized, and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

The description and drawings merely illustrate the principles of the disclosure. Furthermore, all examples recited herein are principally intended expressly to be only for illustrative purpose to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

Some of the below examples are described in connection with a silicon carbide substrate. Alternatively, another wide band gap semiconductor substrate, e.g. a wide band gap wafer, may be processed, e.g. comprising a wide band gap semiconductor material different from silicon carbide. The wide band gap semiconductor wafer may have a band gap larger than the band gap of silicon (1.12 eV). For example, the wide band gap semiconductor wafer may be a gallium arsenide (GaAs) wafer, or a gallium nitride (GaN) wafer.

The first conductivity type may be a p-type and the second conductivity type may be an n-type. Likewise, the first conductivity type may be an n-type and the second conductivity type may be a p-type.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

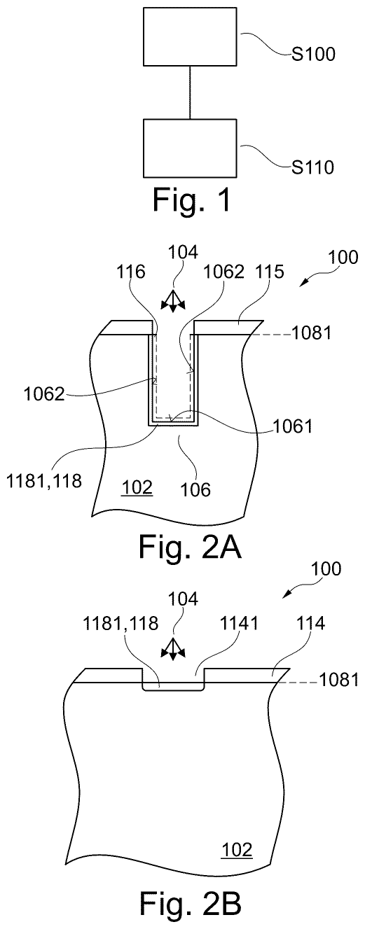

An example of a method of manufacturing a semiconductor device is illustrated by referring to the flowchart of FIG. 1.

Process feature S100 includes forming a doped region of a first conductivity type in a SiC semiconductor body including introducing dopants of the first conductivity type into the SiC semiconductor body by at least one ion implantation process. Forming the doped region further includes introducing dopants of the first conductivity type into the SiC semiconductor body by at least one plasma doping process. A penetration depth of the dopants introduced by the at least one ion implantation process is larger than a penetration depth of the dopants introduced by the at least one plasma doping process.

Process feature S110 includes forming a contact material on a contact surface portion of the doped region. The contact surface portion includes the dopants introduced by at least plasma doping process.

The at least one ion implantation process may be carried out before or after the at least one plasma doping process. When carrying out multiple ion implantation and/or multiple plasma doping processes for forming the doped region, one or more ion implantation processes may be carried out between plasma doping processes or vice versa.

The semiconductor device may be part of an integrated circuit or may be a discrete semiconductor device or a semiconductor module, for example. The semiconductor device may be or may include an insulated gate field effect transistor (IGFET) such as a metal oxide semiconductor field effect transistor (MOSFET) or an insulated gate bipolar transistor (IGBT), or a junction field effect transistor (JFET), for example. The semiconductor device may be a vertical power semiconductor device having a load current flow between the first surface and a second surface opposite to the first surface along a vertical direction. The vertical power semiconductor device may be configured to conduct currents of more than 1A, or more than 10 A, or more than 30 A, or more than 50 A, or more than 75 A, or even more than 100 A, and may be further configured to block voltages between load electrodes, e.g. between collector and emitter on an IGBT, or between drain and source of a MOSFET or JFET, in the range of several hundreds of up to several thousands of volts, e.g. 400 V, 650 V, 1.2 kV, 1.7 kV, 3.3 KV, 4.5 kV, 5.5 kV, 6 kV, 6.5 kV, 10 kV. The blocking voltage may correspond to a voltage class specified in a datasheet of the power semiconductor device, for example.

The semiconductor device may be based on a SiC semiconductor body from a crystalline SiC material. The crystalline SiC material may have a hexagonal crystal lattice, by way of example. For example, the semiconductor material may be 2H-SiC (SiC of the 2H polytype), 6H-SiC or 15R-SiC. According to an example, the semiconductor material is silicon carbide of the 4H polytype (4H-SiC). The SiC semiconductor body may include or consist of a semiconductor substrate having none, one or more than one semiconductor layer, e.g. epitaxially grown layers, thereon. One of the semiconductor layers may be a doped semiconductor layer of a current spread layer, for example.

The first surface may define a front surface or a top surface of the SiC semiconductor body, and the SiC semiconductor body may further have a second surface that may be a back surface or a rear surface of the SiC semiconductor body, for example. The SiC semiconductor body may be attached to a lead frame via the second surface, for example. Over the first surface of the SiC semiconductor body, bond pads may be arranged and bond wires may be bonded on the bond pads, for example.

For realizing a desired current carrying capacity, the SiC semiconductor device may be designed by a plurality of parallel-connected SiC semiconductor device cells. The parallel-connected SiC semiconductor device cells may, for example, be SiC semiconductor device cells formed in the shape of a strip or a strip segment. Of course, the SiC semiconductor device cells can also have any other shape, e.g. circular, elliptical, polygonal such as hexagonal or octahedral. The semiconductor device cells may be arranged in a transistor cell area of the SiC semiconductor body. The transistor cell area may be an area where an emitter region of an IGBT (or a source region of a MOSFET or JFET) and a collector region of an IGBT (or a drain region of a MOSFET or JFET) are arranged opposite to one another along a vertical direction. In the transistor cell area, a load current may enter or exit the SiC semiconductor body of the semiconductor device, e.g. via contact plugs or contact lines on the top surface of the mesa. The semiconductor device may further include an edge termination area that may include a termination structure. In a blocking mode or in a reverse biased mode of the semiconductor device, the blocking voltage between the transistor cell area and a field-free region laterally drops across the termination structure. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example.

The at least one plasma doping process may be any plasma based doping process that enables high dose implants at low energies. Plasma doping processes are also known as PLAD (plasma doping) or PIII (plasma immersion ion implantation). These methods allow for a precise doping of a semiconductor body. For example, a conformal doping of the part of the
semiconductor body at trench sidewalls can be achieved by applying a voltage to a substrate surrounded by a radio frequency (RF) plasma including a dopant gas. Collisions between ions and neutral atoms as well as the biasing of the substrate lead to a broad annular distribution of the dopants allowing for a nearly homogeneous doping over the trench sidewalls. Also a small vertical gradient in dose of doping in the part of the semiconductor body may be achieved by plasma doping. When doping with plasma doping, the SiC semiconductor body, e.g. a semiconductor wafer, is exposed to a plasma including ions of dopants. These ions are accelerated by an electric field towards the substrate and are implanted into an exposed surface of the substrate. An implanted dose can be adjusted or controlled via DC voltage pulses, e.g. negative voltage pulses. A Faraday system allows to adjust or control the dose. For example, two sets of coils, i.e. a horizontal coil and a vertical coil may allow to generate the plasma and keep it homogeneous. An ion density can be adjusted via a distance between the coils and the substrate. Interaction between the vertical coils and the horizontal coils allows to adjust or control homogeneity and the ion density. A penetration depth of the dopants into the semiconductor body and the implant dose may be adjusted via a pulsed DC voltage applied between the SiC semiconductor substrate or body and a shield ring surrounding it.

Forming the doped region may include introducing n- and/or p-type dopants into the SiC semiconductor body. For example, dopants in a semiconductor body comprising SiC may include Al, B, Be, Ga, or any combination thereof for p-type doping, and N, P, or any combination thereof for n-type doping. When forming the doped region by a combination of plasma doping and ion implantation processes, wherein the ion implantation process has a comparatively larger penetration depth of the ions, the formation process of the doped region can be improved with respect to the overall functional purpose of the doped region. Since different portions of the doped region may be associated with different functional purpose, the characteristics of these different portions may be improved by adapting the forming process to the function to be achieved by the respective portion of one continuous doped region. For example, the at least one plasma doping process allows for optimizing that portion of the doped region where a low ohmic contact to n- and/or p-type SiC is to be achieved. Since the plasma doping process inherently dopes the very surface region with high dose and homogeneity within one process step, or alternatively by applying several plasma doping processes for a wider doping profile, an undesired multiplicity of ion implantations having different tilt angles (e.g. undesired in view of manufacturing costs and/or manufacturing time and/or homogeneity of dopant distribution) may be avoided for optimizing that portion of the doped region that is relevant for ohmic contact formation. Furthermore, since dopants in SiC do not diffuse to great extent, this may help to increase the electrically active dopant concentration up to its solubility limit so that the homogeneity of the electrically active dopant concentration along the contact surface, e.g. trench sidewall, is excellent, which is typically not the case for lower surface concentrations. Furthermore, also the total doping concentration (being the sum of electrically active and non-active dopants) is more homogeneous along trench sidewalls the higher the implantation dose is. This helps to achieve an ohmic contact with transitional metals such as titanium or aluminum. Thereby, also the necessity of using critical material (CM class) metals such as nickel can be resolved.

For example, the method may further include forming a first trench into the SiC semiconductor body from a first surface of the SiC semiconductor body. The dopants introduced into the SiC semiconductor body by the at least one plasma doping process may be introduced through a bottom side and sidewalls of the first trench. The dopants introduced into the SiC semiconductor body by the at least one plasma doping process may define a highly doped contact portion of the doped region that is configured for reducing a contact resistance between the doped region and the contact material. The dopants of the doped region that are introduced by the at least one ion implantation process may define at least one functional portion of the doped region that is configured to fulfil a functional purpose, e.g. an electric field shielding function, and/or a threshold voltage adjustment function, and/or a breakdown voltage adjustment function, and/or a conductive path resistivity adjustment function. Formation of the contact portion of the doped region by the at least one plasma doping process may not only allow for avoiding a plurality of ion implantations with different ion implantation tilt angles and further drawbacks but may further enable a uniform and high doping concentration at the contact surface.

For example, after forming the first trench and before introducing the dopants by the at least one plasma doping process, the method may further include processing the bottom side and the sidewalls of the first trench by a sputter etch process. This may allow for removing a native oxide from the bottom side and sidewalls of the first trench. Thus, undesired accumulation of introduced dopants in the native oxide may be avoided. Alternatively, an HF treatment can be applied prior to the plasma doping process.

For example, processing the SiC semiconductor body by the sputter etch process and by the at least one plasma doping process may be carried out in the same process equipment. This may contribute to minimizing the time between the native oxide removal and the at least one plasma doping process.

For example, the method may further include electrically activating the dopants introduced by the at least one plasma doping process by an annealing process including temperatures ranging from 1500° C. to 1800° C., or from 1500° C. to 1700° C., or from 1500° C. to 1600° C. As the doping level introduced by the at least one plasma doping process is comparatively high, a complete electrical activation of the introduced dopants may not be necessary. For example, annealing of Al, or P or N at temperatures around 1600° C. for a duration of less than 1 hour, e.g. 30 minutes, may result in an electrical activation of more than 95% of the introduced dopants. Therefore, an annealing temperature of less than 1800° C., or less than 1700° C., or even less than 1600° C. may be applied for electrical activation of the implanted dopants for minimizing undesired out-diffusion of the implanted dopants.

For example, the method may further include, after introducing the dopants by the at least one plasma doping process and before electrically activating the dopants introduced by the at least one plasma doping process by an annealing process, forming an auxiliary layer on the bottom side and on the sidewalls of the first trench. The auxiliary layer may have a melting point of larger than 1850° C. The auxiliary layer may be beneficial in several ways. For example, the auxiliary layer may act as an out-diffusion barrier layer hindering dopants introduced by the at least one plasma doping process to diffuse out through the bottom side or sidewalls of the first trench. Moreover, the auxiliary layer may prevent a substantial reduction of the surface concentration of the introduced dopants. This may allow for improving the ohmic contact properties between the doped region and the contact material.

For example, a material of the auxiliary layer may include at least one of Si₃N₄, or Al₂O₃, or AlN, or allotropes of carbon, e.g. graphene having melting points at around 1900° C. (e.g. Si₃N₄) or higher (e.g. Al₂O₃, or AlN, or allotropes of carbon).

For example, the method may further include forming a contact layer on the bottom side and the sidewalls of the first trench. The contact material of the contact layer may include a transition metal and/or an alloy of a transition metal.

For example, wherein the transition metal may include at least one of Ni, Al, Ti, e.g. NiAl.

For example, the method may further include forming a second trench at the same time as the first trench. The method may further include at least partly filling or lining the second trench with a protective material before introducing the dopants into the SiC semiconductor body by the at least one plasma doping process through a bottom side and sidewalls of the first trench. For example, the protective material may be polycrystalline silicon and/or a dielectric material such as a sacrificial oxide.

For example, the method may further include removing the protective material from the second trench. The method may further include forming a trench gate structure in the second trench. Forming the trench gate structure in the second trench, e.g. a gate trench, may include forming a trench gate dielectric in the second trench, e.g. by thermal oxidation or deposition. Forming the trench gate structure may further include forming a trench gate electrode on the gate trench dielectric. Forming the trench gate structure may further include a post oxidation anneal in a nitrogen containing atmosphere, for example. The trench gate electrode may include one or a stack of conductive materials, e.g. highly doped polycrystalline silicon and/or carbon and/or metal or metal alloy.

For example, the method may further include, before introducing the dopants of the first conductivity type into the SiC semiconductor body by the at least one plasma doping process, forming a patterned mask layer on the first surface of the SiC semiconductor body. The dopants of the first conductivity type may be introduced into the SiC semiconductor body by the at least one plasma doping process through openings in the patterned mask layer. The patterned mask layer may be formed as a patterned hard mask layer, a patterned resist layer, or a combination thereof, for example. Thereby, a highly doped contact portion at the first surface of the SiC semiconductor body may be prepared.

For example, the method may further include, after introducing the dopants into the SiC semiconductor body by the at least one plasma doping process, forming a trench into the SiC semiconductor body from the first surface of the SiC semiconductor body. Thereafter, the method may further include introducing at least part of the dopants of the first conductivity type into the SiC semiconductor body by the at least one ion implantation process.

For example, the trench may be further processed as a gate trench, e.g. by forming a trench gate dielectric and a trench gate electrode in the gate trench.

For example, the method may further include, before forming the doped region, forming at least one doped layer by introducing dopants into the SiC semiconductor body through a first surface of the SiC semiconductor body. For example, the dopants of the doped layer may be introduced into the SiC semiconductor body by at least one ion implantation process that is blanket or unmasked with respect to a transistor cell area of the semiconductor device.

For example, the at least one doped layer may be or may include a source layer, or a body layer, or a current spread layer, or any combination thereof.

For example, body regions may be formed by patterning the body layer by a trench etch process. Likewise, source regions may be formed by patterning the source layer by the trench etch process. The trench etch process may first etch through the source layer, and thereafter, through the body layer. Each of the body regions may adjoin one of opposite two sidewalls of the trench, for example.

For example, the at least one plasma doping process may be carried out in a process equipment at temperatures ranging from 300° C. to 700° C. Plasma doping at enhanced temperatures may be beneficial with respect to an efficient dopant activation and/or minimization of implantation-induced defects, for example.

Details with respect to structure, or function, or technical benefit of features described above with likewise apply to the exemplary methods described further below. Processing the SiC semiconductor body may comprise one or more optional additional features corresponding to one or more aspects mentioned in connection with the proposed concept or one or more examples described above or below.

The process features may include sub-processes. For example, some or all sub-processes of a process feature described herein may be carried out before or after of between sub-processes of another process feature described herein.

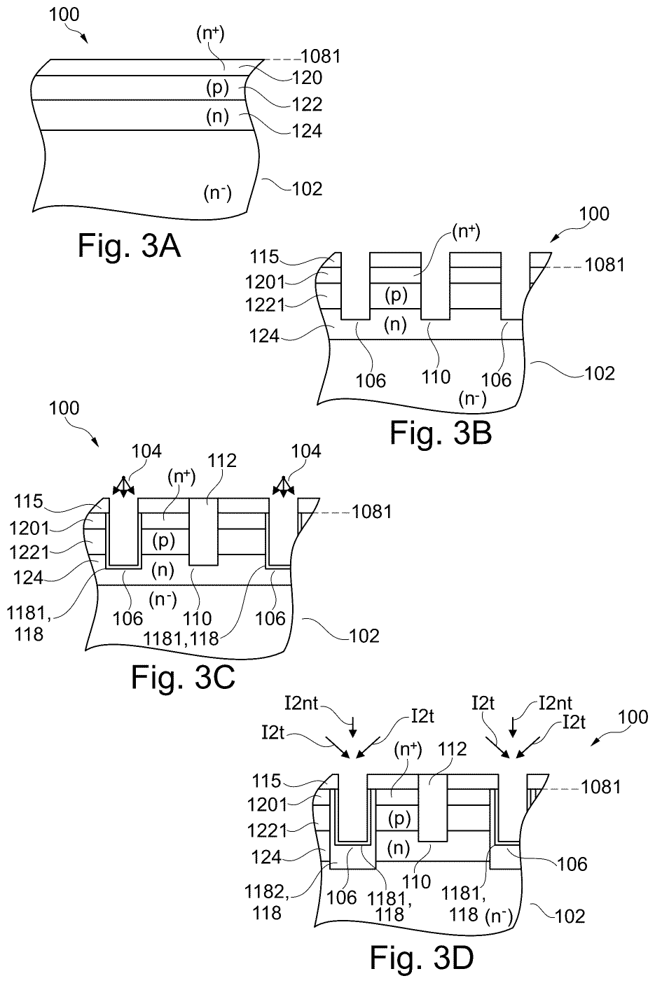

The schematic cross-sectional view of FIG. 2A illustrates process features of an exemplary method of manufacturing a semiconductor device 100 based on the method of FIG. 1.

A first trench 106 is formed into a SiC semiconductor body 102 from a first surface 1081 of a SiC semiconductor body 102. For example, first trench 106 may be formed by an etch process using a patterned mask layer 115, e.g. a hard mask. After forming the first trench 106, dopants of the first conductivity type are introduced into the SiC semiconductor body 102 by at least one plasma doping process 104 through a bottom side 1061 and through sidewalls 1062 of the first trench 106. Thereby, dopants of a first portion 1181 of a doped region 118 are introduced into the SiC semiconductor body 102. The first portion 1181 may define a highly doped contact portion, for example. Further dopants of the first conductivity type may be introduced into the SiC semiconductor body 102 at a larger penetration depth than the dopants of the first portion 1181 by at least one ion implantation process. The at least one ion implantation process may be carried out before and/or after the at least one plasma doping process 104, e.g. by tilted and/or untilted ion implantation(s). After the at least one plasma doping process and after the at least one ion implantation process is carried out, an optional auxiliary layer 116 indicated by a dashed line may be formed on the bottom side 1061 and on the sidewalls 1062 of the first trench 106 for avoiding or minimizing out-diffusion of the introduced dopants during subsequent thermal processing, e.g. electrical activation of the introduced dopants (not illustrated).

The schematic cross-sectional view of FIG. 2B illustrates process features of a further exemplary method of manufacturing a semiconductor device 100 based on the method of FIG. 1. The process features illustrated in FIGS. 2A and 2B may be combined to form doped regions at different positions in the SiC semiconductor body 102 by doping processes each including at least one plasma doping process.

Referring to FIG. 2B, a patterned mask layer 114 is formed on the first surface 1081 of the SiC semiconductor body 102. Thereafter, dopants of the first conductivity type are introduced into the SiC semiconductor body 102 by at least one plasma doping process 104 through an opening 1141 in the patterned mask layer 114. Thereby, dopants of a first portion 1181 of a doped region 118 are introduced into the SiC semiconductor body 102. The first portion 1181 may define a highly doped contact portion for an n- or p-doped region that is electrically connected to a wiring area over the first surface 108 by a contact plug or contact line, for example. Further dopants of the first conductivity type may be introduced into the SiC semiconductor body 102 at a larger penetration depth than the dopants of the first portion 1181 by at least one ion implantation process. The at least one ion implantation process may be carried out before and/or after the at least one plasma doping process 104, e.g. by tilted and/or untilted ion implantation(s). After the at least one plasma doping process and after the at least one ion implantation process is carried out, an auxiliary layer may be formed on the first surface 1081 of the SiC semiconductor body 102, e.g. after removal of the patterned mask layer 114, for avoiding or minimizing out-diffusion of the introduced dopants during subsequent thermal processing, e.g. electrical activation of the introduced dopants (not illustrated).

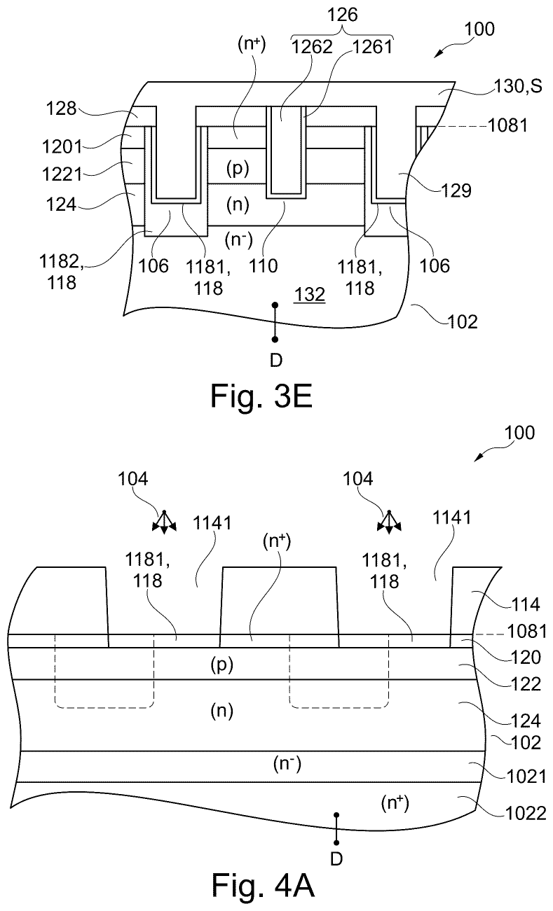

The schematic cross-sectional views of FIGS. 3A to 3E illustrates process features of an exemplary method of manufacturing a semiconductor device 100 based on the method of FIG. 1 and the process features illustrated in FIG. 2A.

Referring to FIG. 3A, before forming the doped region 118 of FIG. 2A, at least one doped layer is formed by introducing dopants into the SiC semiconductor body 102 through the first surface 1081 of the SiC semiconductor body 102, e.g. by one or more ion implantation processes. The ion implantation(s) for forming the at least one doped layer may be unmasked or blanket with respect to a transistor cell area of the semiconductor device. In the illustrated example, the at least one doped layer is exemplified by an n⁺-doped source layer 120, a p-doped body layer 122 and an n-doped current spread layer 124. The n-doped current spread layer 124 has a larger doping concentration than a background doping concentration of the SiC semiconductor body 102 adjoining the n-doped current spread layer 124. As an alternative to forming the n-doped current spread layer 124 by ion implantation, the n-doped current spread layer 124 may likewise be formed by a layer deposition process including, for example, in-situ doping.

Referring to FIG. 3B, a first and second trenches 106, 110 are formed into the SiC semiconductor body 102 from a first surface 1081 of the SiC semiconductor body 102 using the patterned mask layer 115. For example, the first and second trenches 106, 110 may be formed by one or more etch processes. Formation of the first and second trenches 106, 110 patterns or divides the source layer 120 into source regions 1201. Formation of the first and second trenches 106, 110 further patterns or divides the body layer 122 into body regions 1221.

Referring to FIG. 3C, a protective material 112 is formed in the second trench 110. The protective material 112 may fill the second trench 110 (as illustrated in FIG. 3C) or may line or partly fill the second trench 110, and, optionally, parts of the first trench 106 (not illustrated). Dopants of p-type are introduced into the SiC semiconductor body 102 by at least one plasma doping process 104 through a bottom side 1061 and sidewalls 1062 of the first trench 106. Thereby, dopants of a first portion 1181 of a doped region 118 are introduced into the SiC semiconductor body 102.

Referring to FIG. 3D, dopants are introduced into the SiC semiconductor body 102 by at least one tilted ion implantation process 12t and/or non-tilted ion implantation process I2nt through a bottom side 1061 and/or sidewalls 1062 of the first trench 106. Thereby, p-type dopants of a second portion 1182 of the doped region 118 are introduced into the SiC semiconductor body 102.

The at least one ion implantation process I2t, I2nt illustrated in FIG. 3D may also be carried out before, or at least partly before, the at least one plasma doping process 104 illustrated in FIG. 3C. Moreover, cleaning process(es), e.g. for native oxide removal, and/or auxiliary layer(s), e.g. stray oxide, may be formed in the first trench 106 prior to the at least one plasma doping process 104.

Further process features, e.g. as described in the examples above, follow. The further process features may include, inter alia, diffusion barrier deposition, electrical activation of the introduced dopants by thermal annealing, trench gate structure formation in the second trench, wiring area formation over the first surface and the second surface of the SiC semiconductor substrate.

Referring to FIG. 3E, after removal of the protective material 112 from the second trench 110, e.g. gate trench, a trench gate structure 126 including a trench gate dielectric 1261 and a trench gate electrode 1262 is formed. An intermediate dielectric 128 is formed on the first surface 1081 of the SiC semiconductor body 102 as part of a wiring area. A contact material 129, e.g. a conductive filling material, is formed on a contact surface portion of the doped region 118, e.g. at a bottom side and sidewalls of the first trench 106. The contact material 129 is connected to a wiring layer 130, e.g. metal layer. For example, the wiring layer 130 may be a source or emitter electrode S that may also be electrically connected to the source regions 1201 (not illustrated). A wiring layer defining a drain or collector electrode D is also formed on the second surface of the SiC semiconductor substrate 102 for electrically connecting a drift structure 132 in the SiC semiconductor body 102 to the drain or collector electrode D.

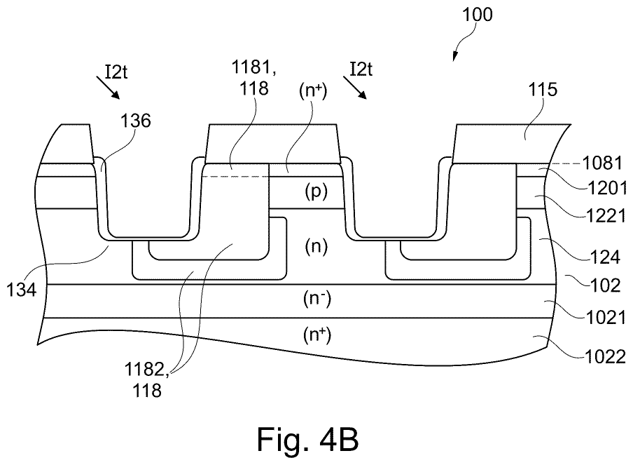

The schematic cross-sectional views of FIGS. 4A to 4B illustrates process features of an exemplary method of manufacturing a semiconductor device 100 based on the method of FIG. 1 and the process features illustrated in FIG. 2B.

Referring to FIG. 4A and similar to the process features described with reference to FIG. 3A, at least one doped layer is formed by introducing dopants into the SiC semiconductor body 102 through a first surface 1081 of the SiC semiconductor body 102, e.g. by one or more ion implantation processes. The ion implantation(s) for forming the at least one doped layer may be unmasked or blanket with respect to a transistor cell area of the semiconductor device 100. In the illustrated example, the at least one doped layer is exemplified by an n⁺-doped source layer 120, a p-doped body layer 122 and an n-doped current spread layer 124. The n-doped current spread layer 124 has a larger doping concentration than a background doping concentration of a first portion 1021 of the semiconductor body 102 adjoining the n-doped current spread layer 124. As an alternative to forming the n-doped current spread layer 124 by ion-implantation, the n-doped current spread layer 124 may likewise be formed by a layer deposition process, for example. The first portion 1021 may be formed by layer deposition on a second portion 1022 of the SiC semiconductor body, e.g. on a highly doped SiC substrate.

A patterned mask layer 114 is formed on the first surface 1081 of the SiC semiconductor body 102. Thereafter, p-type of the first conductivity type are introduced into the SiC semiconductor body 102 by at least one plasma doping process 104 through an opening 1141 in the patterned mask layer 114. Thereby, p-type dopants of a p⁺-doped first portion 1181 of a p-doped region 118 are introduced into the SiC semiconductor body 102. The first portion 1181 may define a highly doped contact portion for a p-doped region 118 that is electrically connected to a wiring area over the first surface 108 by a contact plug or contact line on the first surface 1081, for example. The first portion 1181 may counter-doped areas of the nt-doped source layer 120. A future gate trench position is indicated by a dashed line.

Referring to FIG. 4B, a gate trench 134 is formed into the SiC semiconductor body 102 from a first surface 1081 of the SiC semiconductor body 102 using a patterned mask layer 115. For example, the gate trench 134 may be formed by one or more etch processes. Formation of gate trench 134 patterns or divides the source layer 120 into source regions 1201. Formation of the gate trench 134 further patterns or divides the body layer 122 into body regions 1221.

After forming a sacrificial layer 136, e.g. a sacrificial oxide layer, on the bottom side and sidewalls of the gate trench 134, further p-type dopants are introduced into the SiC semiconductor body 102 by at least one tilted ion implantation 12t to form a second portion 1182 of the doped region 118 at a larger penetration depth than the dopants of the first portion 1181. The second portion 1182 is exemplified in FIG. 4B by a combination of two sub-portions associated with ion implantations having different tilt angle and/or ion implantation energy.

Further process features, e.g. as described in the examples above, follow. The further process features may include, inter alia, removal of the sacrificial layer, electrical activation of the introduced dopants by thermal annealing, gate structure formation in the gate trench, contact material formation on the first portion by a contact plug or contact line, wiring area formation over the first surface and the second surface of the SiC semiconductor substrate 102. The semiconductor device 100 based on the process features of FIGS. 4A and 4B may be a trench transistor having a channel region only on one of opposite two sidewalls of the gate trench.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of forming a semiconductor device, the method comprising:
forming a doped region of a first conductivity type in a SiC semiconductor body, comprising:
introducing dopants of the first conductivity type into the SiC semiconductor body by at least one ion implantation process;
introducing dopants of the first conductivity type into the SiC semiconductor body by at least one plasma doping process, wherein a penetration depth of the dopants introduced by the at least one ion implantation process is larger than a penetration depth of the dopants introduced by the at least one plasma doping process; and
forming a contact material on a contact surface portion of the doped region, wherein the contact surface portion includes the dopants introduced by at least plasma doping process.

2. The method of claim 1, further comprising:
forming a first trench in the SiC semiconductor body from a first surface of the SiC semiconductor body, wherein the dopants introduced into the SiC semiconductor body by the at least one plasma doping process are introduced through a bottom side and sidewalls of the first trench.

3. The method of claim 2, further comprising:
after forming the first trench and before introducing the dopants by the at least one plasma doping process, processing the bottom side and the sidewalls of the first trench by a sputter etch process.

4. The method of claim 3, wherein the sputter etch process and the at least one plasma doping process are carried out in a same process equipment.

5. The method of claim 2, further comprising:
electrically activating the dopants introduced by the at least one plasma doping process by an annealing process including temperatures ranging from 1500° C. to 1800° C.

6. The method of claim 5, further comprising:
after introducing the dopants by the at least one plasma doping process and before the annealing process, forming an auxiliary layer on the bottom side and on the sidewalls of the first trench, wherein the auxiliary layer has a melting point of larger than 1850° C.

7. The method of claim 6, wherein a material of the auxiliary layer includes at least one of Si₃N₄, or Al₂O₃, or AlN, or allotropes of carbon.

8. The method of claim 2, further comprising:
forming a contact layer on the bottom side and the sidewalls of the first trench, wherein a contact material of the contact layer includes a transition metal and/or an alloy of a transition metal.

9. The method of claim 8, wherein the transition metal includes at least one of Ni, Al, and Ti.

10. The method of claim 8, further comprising:
forming a second trench at a same time as the first trench; and
before introducing the dopants into the SiC semiconductor body by the at least one plasma doping process, at least partly filling or lining the second trench with a protective material.

11. The method of claim 10, further comprising:
removing the protective material from the second trench; and
forming a trench gate structure in the second trench.

12. The method of claim 1, further comprising:
before introducing the dopants of the first conductivity type into the SiC semiconductor body by the at least one plasma doping process, forming a patterned mask layer on a first surface of the SiC semiconductor body, wherein the dopants of the first conductivity type are introduced into the SiC semiconductor body by the at least one plasma doping process through openings in the patterned mask layer.

13. The method of claim 12, further comprising:
after introducing the dopants into the SiC semiconductor body by the at least one plasma doping process, forming a trench in the SiC semiconductor body from the first surface of the SiC semiconductor body; and
after forming the trench, introducing at least part of the dopants of the first conductivity type into the SiC semiconductor body by the at least one ion implantation process.

14. The method of claim 1, further comprising:
before forming the doped region, forming at least one doped layer by introducing dopants into the SiC semiconductor body through a first surface of the SiC semiconductor body.

15. The method of claim 14, wherein the at least one doped layer includes a source layer, or a body layer, or a current spread layer, or any combination thereof.

16. The method of claim 15, wherein:
body regions are formed by patterning the body layer by a trench etch process; and/or
source regions are formed by patterning the source layer by the trench etch process.

17. The method of claim 1, wherein the at least one plasma doping process is carried out in a process equipment at temperatures ranging from 300° C. to 700° C.
